(19) United States
(12) Patent Application Publication
(10) Pub. No.: US 2026/0140440 A1
(43) Pub. Date: May 21, 2026

(54) METHOD FOR FORMING PHOTORESIST THIN FILM REACTIVE TO EXTREME ULTRAVIOLET RAYS, AND PHOTORESIST THIN FILM FORMED THEREBY

(71) Applicant: DONGJIN SEMICHEM CO., LTD., Incheon (KR)

(72) Inventors: So Jeong YEO, Gwangju (KR); Jang Keun SIM, Yongin-si (KR); Jae Woo LEE, Incheon (KR); Jun Young KIM, Jeonju-si (KR); Pil Soo KIM, Hwaseong-si (KR); Da Som KIM, Cheongju-si (KR)

(21) Appl. No.: 19/388,852

(22) Filed: Nov. 13, 2025

Related U.S. Application Data
(63) Continuation of application No. PCT/KR2024/006980, filed on May 23, 2024.

(30) Foreign Application Priority Data
May 23, 2023 (KR) 10-2023-0066608
May 23, 2024 (KR) 10-2024-0066919

(51) Int. Cl. G03F 7/004; C23C 16/44; C23C 16/455; G03F 7/16

(52) U.S. Cl. CPC G03F 7/0042; C23C 16/4408; C23C 16/45553; G03F 7/167

(57) ABSTRACT

A method for forming a hydrophobic photoresist thin film includes the steps of: injecting a first precursor and an oxygen source into a chamber in which a substrate is disposed, so as to form a thin film including hydrophilic groups; and injecting a second precursor to modify the thin film including the hydrophilic groups and form a modified layer. The photoresist thin film formed thereby does not contain hydroxyl groups and thus exhibits hydrophobicity.

### CROSS-REFERENCE TO RELATED APPLICATIONS

This application is a Continuation of International Application No. PCT/KR2024/006980 filed May 23, 2024, which claims priority from Korean Application Nos. 10-2023-0066608 filed May 23, 2023 and 10-2024-0066919 filed May 23, 2024. The aforementioned applications are incorporated herein by reference in their entireties.

### TECHNICAL FIELD

The present invention relates to a method for forming a photoresist thin film and a photoresist thin film formed thereby, and more particularly, to a method for forming a thin film, by forming a thin film including a hydrophilic group using two types of precursors and then modifying the thin film to form a modified layer, and to a photoresist thin film formed thereby.

### RELATED ART

Photoresist (PR) is a chemical substance whose properties change in response to light.

Photoresist's chemical properties change when exposed to light. Depending on the type, it may harden or change to dissolve more easily when exposed to light. Photolithography utilizes this change in photoresist properties to selectively remove weakened areas, distinguishing between those that will be used as circuits and those that will not, and creates a fine circuit pattern in three dimensions, much like lithography.

The photolithography process is a key step in the manufacturing of thin film transistors. In this process, photoresist is applied as a thin layer on the thin film transistor substrate. After a photomask is placed over the photoresist, which defines the areas where the electronic circuit pattern will be formed and the rest, and then exposed to light, the photoresist's properties change between the illuminated and unilluminated areas. The solubility difference between the two areas is then exploited to remove the more soluble photoresist through a development process.

The remaining deposition material in the areas where the photoresist has disappeared is removed through an etching process, while the remaining deposition material under the photoresist remains intact, protected by the photoresist.

As it is impossible to form fine patterns smaller than 50 nm using conventional photoresists with krypton fluoride (248 nm) and argon fluoride (193 nm) light sources, lithography processes using short-wavelength light sources and chemically amplified deep ultraviolet (DUV) photoresists that respond to these short-wavelength light sources have been developed to integrate more circuits into a smaller area.

The short-wavelength light sources emerging include extreme ultraviolet (EUV) (13 nm) light sources, ion beams, and X-rays. The use of EUV light sources enables circuit designs of 0.1 μm or smaller, and is expected to enable the production of semiconductors 100 times faster and with 100 times the capacity compared to current processes.

Organic-based chemically amplified resist (CAR), which is a typical photoresist, has been used as a standard material up to the argon fluoride generation; however, with the introduction of extreme ultraviolet (EUV) radiation and process refinement, due to problems in which (1) the low cross-section of carbon and oxygen, which are the main components of CAR, for EUV wavelength photons results in very poor photon absorption efficiency, (2) acid diffusion leads to deterioration of uniformity and roughness, and 3 the low mechanical strength of organic-based photoresists leads to pattern collapse during the development process. Accordingly, the need for the development of new inorganic photoresists that (1) possesses high photon absorption at the EUV wavelength and (2) has superior mechanical strength and etch resistance, thereby satisfying RLS (Resolution, LER/LWR, Sensitivity) characteristics has emerged.

Recently, inorganic photoresists using liquid and vapor phase chemical reactions as a coating method are recognized globally as the only alternative technology for forming ultra-fine patterns; however, the development of core technologies for related materials, processes, and equipment remains lacking. Therefore, to secure technological competitiveness and lead the next-generation extreme ultraviolet patterning technology, the development of inorganic photoresist materials and processes is essential.

### SUMMARY

An aspect of the present invention is to provide a method for forming a photoresist thin film having an improved photon absorption rate of extreme ultraviolet rays and excellent etching resistance, and a photoresist thin film formed thereby.

The aspect of the present invention is not limited to those mentioned above, and other aspects not mentioned will be clearly understood by those skilled in the art from the description below.

An embodiment of the present invention provides a method for forming a hydrophobic photoresist thin film, including the steps of: injecting a first precursor and an oxygen source into a chamber in which a substrate is disposed, so as to form a thin film including hydrophilic groups on the substrate; and injecting a second precursor into the chamber and thereby modifying the thin film including the hydrophilic groups, so as to form a modified layer.

The method may further include supplying a purge gas to the chamber after forming the thin film including hydrophilic groups, thereby removing an reacted portion of the oxygen source.

The method may further include, after forming the modified layer, supplying a purge gas to the chamber to remove an unreacted portion of the second precursor.

The forming of the modified layer may be performed without supplying a reactant.

The hydrophilic groups may include one or more hydroxyl groups.

In an embodiment of the present invention, the first precursor may include a compound represented by Chemical Formula 1 below.

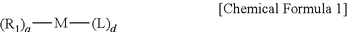

wherein a and d are integers that satisfy conditions 0≤a≤5, 0≤d≤5, and 0<a+d<5; M is a Period 5 metal; R₁ is selected from the group consisting of a linear, branched or cyclic alkyl group, a linear, branched or cyclic alkenyl group, and aryl group; and L is each independently a hydrolyzable ligand.

In an embodiment of the present invention, the M may be one metal selected from the group consisting of Te, Sb, Sn, and In.

In an embodiment of the present invention, the L may be selected from the group consisting of an ester group, an amine group, an amide group, an alkoxy group, a carbonyl group, and an aldehyde group.

In an embodiment of the present invention, the second precursor may include a compound represented by Chemical Formula 2 below.

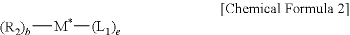

wherein b and e are integers that satisfy conditions 1≤b≤5, 0≤e≤5, and 1≤b+e≤5; M* is a Period 5 metal; R₂ is selected from the group consisting of a linear, branched or cyclic alkyl group, a linear, branched or cyclic alkenyl group, and aryl group; and L₁ is a hydrolyzable ligand.

In an embodiment of the present invention, the M* may be one metal selected from the group consisting of Te, Sb, Sn, and In.

In an embodiment of the present invention, the L₁ may be selected from the group consisting of an ester group, an amine group, an amide group, an alkoxy group, a carbonyl group, and an aldehyde group. In an embodiment of the present invention, the oxygen source may be one selected from the group consisting of water (H₂O), oxygen (O₂), ozone (O₃), and hydrogen peroxide (H₂O₂).

At least one of the M or the M* may include Te.

Both the M and the M* may be Te.

Another embodiment of the present invention provides a photoresist thin film formed according to the method described herein.

In an embodiment of the present invention, the hydrophobic photoresist thin film may include a compound represented by Chemical Formula 3 below.

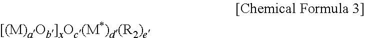

wherein M and M* are each independently a Period 5 metal; R₂ is selected from the group consisting of a linear, branched or cyclic alkyl group, a linear, branched or cyclic alkenyl group, and an aryl group; and a′≥4, b′≥8, c′≥4, d′≥8, e′≥8, x≥1.

At least one of the M or the M* may include Te.

Both the M and the M* may be Te.

The R₂ may include a branched alkyl group or a halogenated alkyl group.

In an embodiment of the present invention, the hydrophobic photoresist thin film may exhibit a contact angle with water of 60° or higher.

In an embodiment of the present invention, infrared spectroscopy of the hydrophobic photoresist thin film may present no hydroxy peak at 3200-3400 cm⁻¹.

According to an embodiment of the present invention, a photoresist thin film can be formed with an increased photon absorption rate of extreme ultraviolet rays and excellent etching resistance.

Additionally, a desired thin film thickness can be formed through a first precursor.

By sequentially depositing a first precursor and a second precursor, and not containing direct bonds between hydroxyl groups and metal in a thin film, hydrophobicity can be achieved.

The effects of the present invention are not limited to the effects described above, and should be understood to include all effects that are inferable from the configuration of the present invention described in the detailed description and claims of the present invention.

### BRIEF DESCRIPTION OF THE DRAWINGS

FIG. 1 is a schematic view of a method for forming a photoresist thin film according to the present invention.

FIG. 2 is an infrared spectroscopy (IR) analysis graph within a hydroxyl group (OH) peak range.

### DETAILED DESCRIPTION

Hereinafter, the present invention will be described with reference to the accompanying drawings. However, the present invention may be implemented in various different forms and, therefore, is not limited to the embodiments described herein. In the drawings, in order to clearly explain the present invention, portions unrelated to the description are omitted, and similar portions are given similar reference numerals throughout the specification.

Throughout the specification, when a portion is said to be “connected (linked, contacted, combined)” with another portion, this includes not only a case of being “directly connected” but also a case of being “indirectly connected” with another member in between. In addition, when a portion is said to “include” a certain component, this does not mean that other components are excluded, but that other components may be added, unless specifically stated to the contrary.

The terms used herein are merely used to describe specific embodiments and are not intended to limit the present invention. Singular expressions include plural expressions unless the context clearly dictates otherwise. In this specification, it should be understood terms such as “include” or “have” are to designate the presence of features, numbers, steps, operations, components, parts, or combinations thereof described in the specification, but are not to exclude the presence or addition of one or more other features, numbers, steps, operations, components, parts, or combinations thereof.

The term “substituted or unsubstituted” as used herein means a group that is substituted or unsubstituted with one or more substituents selected from the group consisting of: deuterium; halogen; cyano; nitro; hydroxy; carbonyl; ester; imide; amide; amino; carboxy; sulfonic acid; sulfonamide; phosphine oxide; alkoxy; alkylcarbonyl; alkoxycarbonyl; sulfonyloxy; aryloxy; alkylthioxy; arylthioxy; alkylsulfoxy; arylsulfoxy; silyl; boron; aryl; and heteroaryl groups, or a group that is substituted or unsubstituted with two or more of the above-mentioned substituents linked together.

As used herein, examples of halogen include fluorine, chlorine, bromine, or iodine.

As used herein, the oxygen of the ester group may be substituted with a straight-chain, branched-chain, or cyclic-chain alkyl group having 1 to 25 carbon atoms or an aryl group having 6 to 25 carbon atoms.

As used herein, specific examples of alkyl groups include, but are not limited to, methyl, ethyl, propyl, n-propyl, isopropyl (iPr), butyl, n-butyl, isobutyl, tert-butyl (tBu), sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohectylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl. The alkyl group may be substituted or unsubstituted; if substituted, examples of the substituent are as described above.

As used herein, an alkoxy group is a functional group in which the aforementioned alkyl group is bonded to one end of an ether group (—O—), and the description of the above alkyl group applies, except that the functional group is bonded to an ether group (—O—). For example, the alkyl group may be linear, branched, or cyclic. The carbon number of the alkoxy group is not particularly limited, but may range from 1 to 20 carbon atoms. Specifically, examples thereof include, but are not limited to, methoxy, ethoxy, n-propoxy, isopropoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, cycloheptoxy, benzyloxy, and p-methylbenzyloxy. The alkoxy group may be substituted or unsubstituted; if substituted, examples of the substituent are as described above.

As used herein, the amine group may be selected from the group consisting of —NH₂, a monoalkylamine group, a dialkylamine group, an N-alkylarylamine group, a monoarylamine group, a diarylamine group, an N-arylheteroarylamine group, an N-alkylheteroarylamine group, a monoheteroarylamine group, and a diheteroarylamine group, and the number of carbon atoms is not particularly limited, but may be 1 to 30. Specific examples of amine groups include, but are not limited to, a methylamine group, a dimethylamine group, an ethylamine group, a diethylamine group, a phenylamine group, a naphthylamine group, a biphenylamine group, anthracenylamine group, a 9-methyl-anthracenylamine group, a diphenylamine group, a ditolylamine group, an N-phenylbiphenylamine group, an N-phenylnaphthylamine group, an N-biphenylnaphthylamine group, a ditolylamine group, an N-phenyltolylamine group, a triphenylamine group, an N-naphthylfluorenylamine group, an N-phenylphenanthrenylamine group, an N-biphenylphenanthrenylamine group, an N-phenylfluorenylamine group, an N-phenylterphenylamine group, an N-phenanthrenylfluorenylamine group, and an N-biphenylfluorenylamine group. The amine group may be substituted or unsubstituted, and examples of substituents when substituted are as described above.

As used herein, the amide group may be bonded to the nitrogen of the amide group by hydrogen, a linear alkyl group having 1 to 30 carbon atoms, a branched alkyl group having 3 to 30 carbon atoms, a cyclic alkyl group having 3 to 30 carbon atoms, an aryl group having 6 to 30 carbon atoms, or any combinations thereof.

Hereinafter, an embodiment of the present invention will be described in detail with reference to the accompanying drawings.

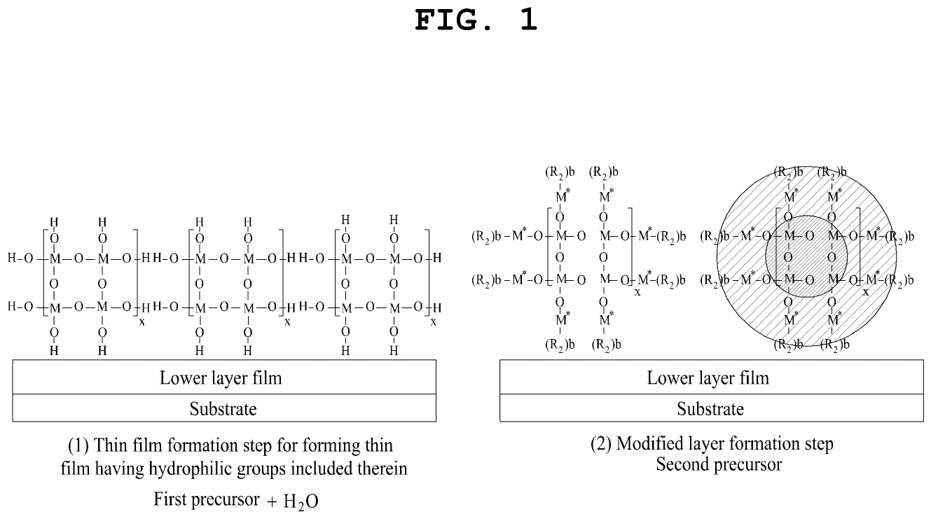

FIG. 1 is a schematic view of a method for forming a photoresist thin film according to the present invention.

Referring to FIG. 1, a method for forming a hydrophobic photoresist thin film according to an embodiment of the present invention will be described below.

A method for forming a hydrophobic photoresist thin film according to an embodiment of the present invention includes the steps of: injecting a first precursor and an oxygen source into a chamber in which a substrate is located, so as to form a thin film having hydrophilic groups included therein; and injecting a second precursor to modify the thin film having the hydrophilic groups included therein and form a modified layer.

After forming the thin film containing the hydrophilic groups, the method may further include supplying a purge gas to the chamber to remove unreacted oxygen sources.

The thin film including hydrophilic groups includes hydroxyl groups.

The first precursor may include a structure represented by chemical formula 1 below.

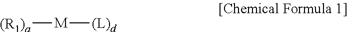

wherein a and d are integers, satisfying 0≤a≤5, 0≤d≤5, and 0<a+d<5; M is a Period 5 metal; R₁ is selected from a linear, branched, or cyclic alkyl group, a linear, branched, or cyclic alkenyl group, and an aryl group; and L is a hydrolyzable ligand.

More specifically, a may be an integer from 0 to 4, and d may be an integer from 0 to 4. Specifically, when a+d=4, a may be 0 and d may be 4, or a may be 1 and d may be 3.

Specifically, M may be one metal selected from Period 5 metals consisting of Te, Sb, Sn, and In. More specifically, M may be Te or Sn. In photoresists, higher absorbance generally corresponds to lower sensitivity, which is generally more advantageous. Throughout the present disclosure, the expressions “better sensitivity,” “improved sensitivity,” or “superior sensitivity” refer to relatively lower sensitivity resulting from the higher absorbance of the material. From this perspective, the order of ascending superiority is In<Sn<Sb<Te.

R₁ may be selected from a linear, branched, or cyclic alkyl group, a linear, branched, or cyclic alkenyl group, and an aryl group.

Specifically, R₁ is selected from hydrogen, a substituted or unsubstituted linear alkyl group having 1 to 20 carbon atoms, a substituted or unsubstituted branched alkyl group having 3 to 20 carbon atoms, a substituted or unsubstituted cyclic alkyl group having 3 to 20 carbon atoms, a substituted or unsubstituted alkenyl group having 2 to 20 carbon atoms, or a substituted or unsubstituted aryl group having 6 to 30 carbon atoms.

The alkyl and aryl groups may be halogenated. The precursor has functional groups such as —(CH₂)ₙCF₃, —(CH₂)ₙI, —(CH₂)ₘCHCH₂, but these are examples and the functional groups are not limited thereto.

Alkyl groups have a characteristic of favoring metal bonding during EUV exposure. Branched alkyl groups exhibit a greater propensity for metal bonding, which may lead to improved sensitivity. When R₁ is absent, the group exhibits excellent reactivity with water, which may be advantageous for metal oxide film formation.

That is, when R₁ is unsubstituted, branched alkyl groups exhibit greater metal bonding during EUV exposure, leading to improved sensitivity. Specifically, isopropyl and tert-butyl groups provide a superior sensitivity, and more specifically, tert-butyl groups provide a superior sensitivity.

An alkenyl group is a straight-chain or branched aliphatic hydrocarbon group and refers to an aliphatic unsaturated alkenyl group containing one or more double bonds.

An aryl group is a substituent in which all atoms of the cyclic substituent have p-orbitals and these p-orbitals form conjugation, and may include a monocyclic or fused ring polycyclic (i.e., a ring that shares adjacent pairs of carbon atoms) functional group.

Aryl groups may provide similar effects to linear alkyl groups.

L is a hydrolyzable ligand, which may be selected from an ester group, an amine group, an amide group, an alkoxy group, a carbonyl group, and an aldehyde group.

Specifically, the ester group may be selected from a formate group, an acetyl group, a propionate group, and a phenyl acetate group.

Specifically, the amine group may be a dialkylamine group. More specifically, the amine group may be a dimethylamine group.

The amine group may have the best reactivity with water.

The oxygen source may be one selected from water, oxygen, ozone, and hydrogen peroxide.

The first precursor is deposited using a chemical vapor deposition (CVD) process. This process may be categorized into thermal, plasma, and light-based processes, depending on the external energy used in the CVD process. This process involves placing a wafer in a vacuum chamber isolated from the outside and supplying a gas containing the raw material for the desired thin film. This process deposits a thin film without altering the properties of the substrate due to plasma, heat, or other factors.

During the first precursor deposition process, oxide particles are formed at intervals and physically or chemically adsorbed.

The first precursor may adjust the thickness of the photoresist thin film.

A purge step may be further performed following this step, and during the purge step, a purge gas may be supplied to the chamber to remove the unreacted oxygen source.

The next step is to introduce a second precursor to modify the thin film, which contains the hydrophilic group, thereby forming a modified layer. After forming the modified layer, an additional step of supplying a purge gas to the chamber to remove unreacted second precursor may be included.

The forming of the modified layer does not include a reactant.

The second precursor includes a structure represented by chemical formula 2 below and may be represented by chemical formula 2 below.

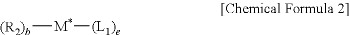

wherein 1≤b≤5, 0≤e≤5, 1≤b+e≤5, b and e are integers, M* is a Period 5 metal, R₂ is selected from a linear, branched or cyclic alkyl group, a linear, branched or cyclic alkenyl group and an aryl group, and L₁ is a hydrolyzable ligand.

Specifically, when b is an integer from 0 to 4, e may be an integer from 0 to 4. More specifically, b+e=4 may be satisfied. When b equals 3, e may be 1. Alternatively, b+e=2 may be satisfied. When b equals 1, e may be 1.

The M* may be any one metal selected from Te, Sb, Sn, and In, which belong to Period 5 metals. More specifically, the M* may be Sn or Te.

The M and M* may be the same or different. At least one of the M and M* may include Sn. At least one of the M and M* may include Te. Both of the M and M* may be Te. Specifically, when M is Sn, M* may be Te. When M is Te, M* may be Sn. When M is Te, M* may be Te. When M is Sn, M* may be Sn.

In photoresists, a higher light-absorbance indicates a lower and more superior sensitivity. From this perspective, the superiority may increase in the following order: In, Sn, Sb, and Te.

The R₂ may be selected from a linear, branched, or cyclic alkyl group, a linear, branched, or cyclic alkenyl group, or an aryl group. Furthermore, when R₂ includes a halogenated alkyl group or a branched alkyl group, the sensitivity may be superior.

Specifically, R₂ is selected from hydrogen, a substituted or unsubstituted linear alkyl group having 1 to 20 carbon atoms, a substituted or unsubstituted branched alkyl group having 3 to 20 carbon atoms, a substituted or unsubstituted cyclic alkyl group having 3 to 20 carbon atoms, a substituted or unsubstituted alkenyl group having 2 to 20 carbon atoms, and a substituted or unsubstituted aryl group having 6 to 30 carbon atoms.

Specifically, R₂ may include a branched alkyl group or a halogenated alkyl group.

More specifically, R₂ may include tert-butyl or —CH₂CH₂I.

Alkyl groups have a characteristic of favoring metal bonding during EUV exposure. In particular, bonding with metal is better facilitated when the alkyl group is branched rather than linear or cyclic.

An alkenyl group is a straight-chain or branched aliphatic hydrocarbon group and refers to an aliphatic unsaturated alkenyl group containing one or more double bonds.

An aryl group is a substituent in which all atoms of the cyclic substituent have p-orbitals and these p-orbitals form conjugation, and may include a monocyclic or fused ring polycyclic (i.e., a ring that shares adjacent pairs of carbon atoms) functional group.

Aryl groups may yield similar effects as linear alkyl groups.

L₁ is a hydrolyzable ligand that may be selected from an ester group, an amine group, an amide group, an alkoxy group, a carbonyl group, and an aldehyde group.

Specifically, the ester group may be selected from a formate group, an acetyl group, a propionate group, and a phenyl acetate group.

Specifically, the amine group may be a dialkylamine group. More specifically, the amine group may be a dimethylamine group.

L₁ is removed by a hydrolysis reaction during the thin film formation.

In the depositing of the second precursor, the second precursor may penetrate the gap and remove the hydroxo moiety, forming a side chain.

The second precursor may leave oxo residues and remove the hydroxo moiety. This results in the final thin film exhibiting hydrophobicity.

The Atomic Layer Deposition (ALD) process involves precursor supply, purge, reactant supply, and purge processes to form a deposition process. However, the method according to the present invention does not include the reactant supply and only performs the precursor supply and purge steps. This process may improve sensitivity and storage stability.

In this case, if the reactants are added and the purge process is further performed, a metal oxide film is formed.

According to the present invention, processes of (i) introducing a first precursor and an oxygen source into a chamber where a substrate is located to form a thin film containing hydrophilic groups, (ii) purging the film, (iii) introducing a second precursor to modify the thin film containing hydrophilic groups to form a modified layer, and (iv) purging constitute one cycle. This cycle may be repeated 5 to 300 times. The hydrophobic photoresist thin film thus deposited may have a thickness ranging from 10 to 600 nm. If the thickness of the thin film is controlled to be small, it may be used not only as a photoresist thin film but also as an underlayer.

A photoresist thin film according to an embodiment of the present invention may be formed according to the forming method above, or may be formed by a method other than the above-described forming method.

The photoresist thin film includes a structure represented by chemical formula 3 below, and may be represented by chemical formula 3 below.

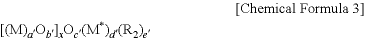

wherein M and M* are each independently a Period 5 metal, R₂ is selected from a linear, branched or cyclic alkyl group, a linear, branched or cyclic alkenyl group and an aryl group, and a′≥4, b′≥8, c′≥4, d′≥8, e′≥8, x≥1.

The M and M* may each independently be one metal selected from Te, Sb, Sn and In, which belong to Period 5 metals. In photoresists, a higher light-absorbance indicates a lower and more superior sensitivity. From this perspective, the degree of superiority increases in the following order: In, Sn, Sb, and Te.

Specifically, when the M is selected from Sn and Te, M* may be selected from Sn and Te.

The above M and M* may include at least Te.

More specifically, when M is Sn, M* may be Sn, when M is Sn, M* may be Te, when M is Te, M* may be Te, and when M is Te, M* may be Sn.

The R₂ may be selected from a linear, branched, or cyclic alkyl group, a linear, branched, or cyclic alkenyl group, and an aryl group.

R₂ is selected from hydrogen, a substituted or unsubstituted linear alkyl group having 1 to 20 carbon atoms, a substituted or unsubstituted branched alkyl group having 3 to 20 carbon atoms, a substituted or unsubstituted cyclic alkyl group having 3 to 20 carbon atoms, a substituted or unsubstituted alkenyl group having 2 to 20 carbon atoms, and a substituted or unsubstituted aryl group having 6 to 30 carbon atoms.

Specifically, R₂ may include a branched alkyl group or a halogenated alkyl group.

More specifically, R₂ may comprise a tert-butyl group (tBu) or —CH₂CH₂I.

a′≥4, b′≥8, c′≥4, d′≥8, e′≥8, and x≥1 are satisfied.

Specifically, a′≥12, b′≥24, c′≥12, d′≥24, e′≥24, and x≥3 may be satisfied.

More specifically, 12≤a′≤80, 24≤b′≤160, 12≤c′≤80, 24≤d′≤160, 24≤e′≤480, and 3≤x≤20 may be satisfied.

[Chemical Formula 3] above may have, for example, a repeating unit as in [Chemical Formula 4] below.

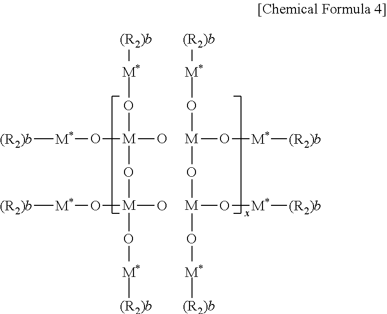

Here, b is an integer from 1 to 3.

The repeating unit of [Chemical Formula 4] may grow in the transverse, longitudinal, or bidirectional directions.

[Chemical Formula 5], [Chemical Formula 6], [Chemical Formula 7], and [Chemical Formula 8] below are examples of thin film structures when x=1, x=2, x=3, and x=4, respectively. The form in which the thin film grows is not limited thereto, and various variations are possible. The bond angles for each atom may vary.

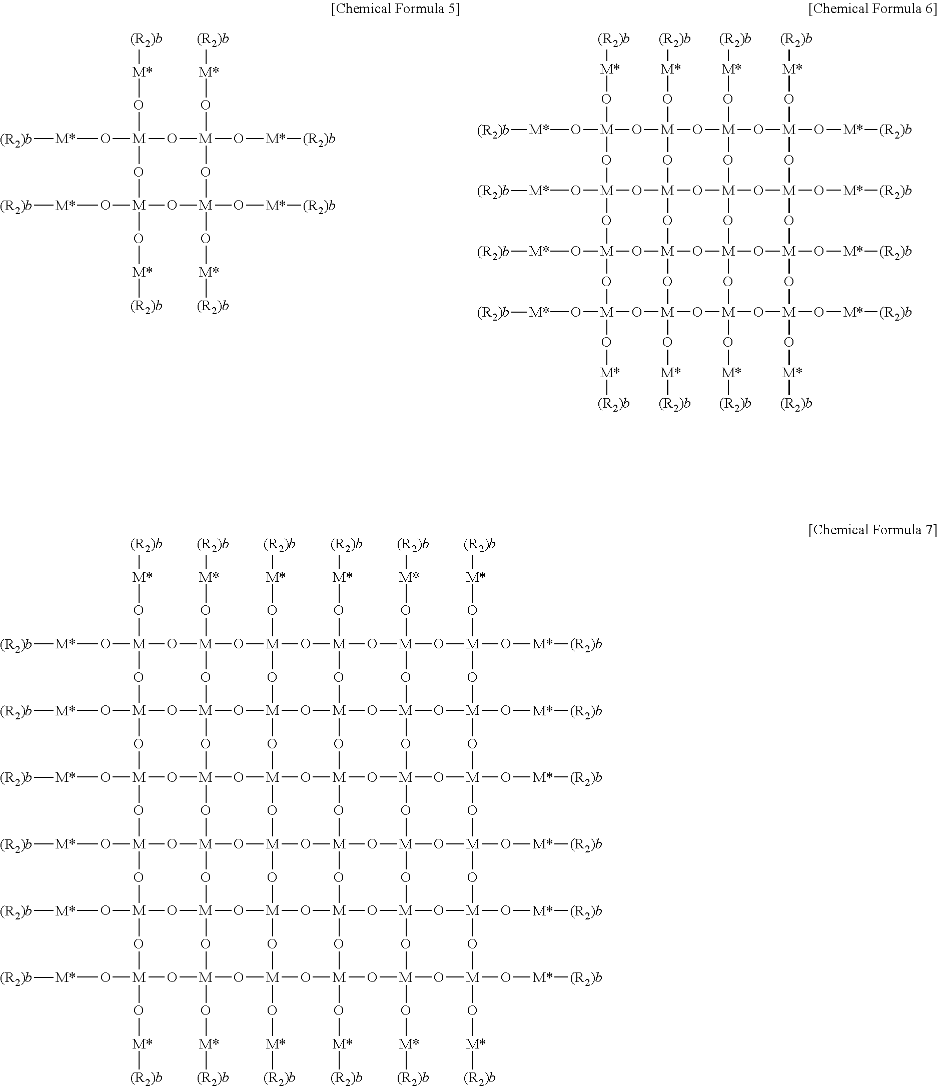

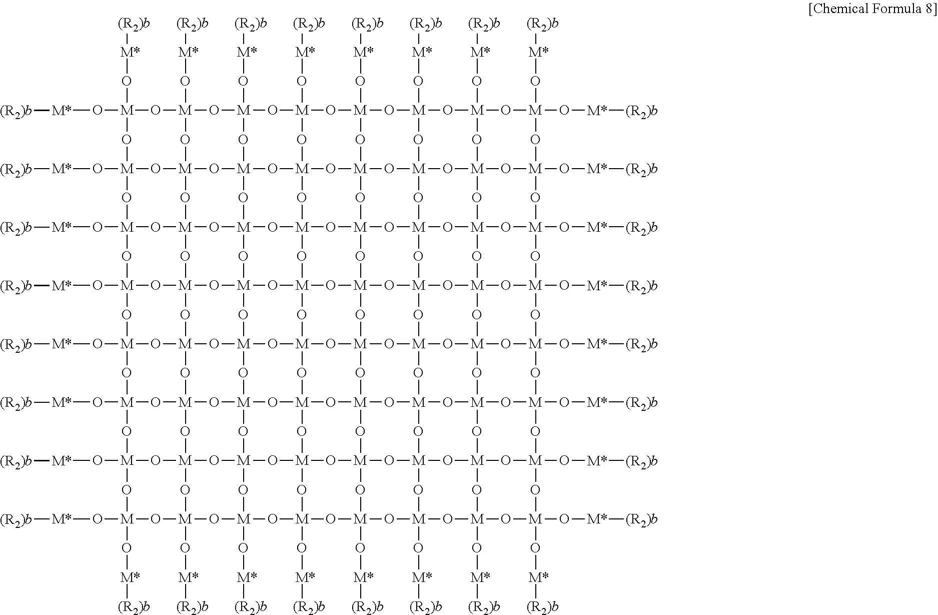

The photoresist of the present invention may be formed to have a thickness of 5 nm to 30 nm (50 Å to 300 Å). In [Chemical Formula 3], when a′=4, b′=4, c′=8, d′=8, and e′=8, or 16 or 24, the photoresist may be expressed in the form of [Chemical Formula 4]. When X=1, the length of the unit cell may be 1.6 nm to 2.0 nm.

The contact angle of the photoresist thin film with water may be 60° or more. The presence of R₂ is essential for extreme ultraviolet light photoreaction. The contact angle refers to the angle between a water droplet and the solid interface when the water is dropped on the solid, and a small contact angle indicates high wettability and hydrophilicity, while a large contact angle indicates low wettability and hydrophobicity.

Generally, a metal oxide film is hydrophilic, and the water-contact angle is smaller than 50°. However, the thin film according to the present invention exhibits low wettability and hydrophobicity with a contact angle of 60° or more.

Since the photoresist thin film according to the present invention does not contain a direct bond between a metal and a hydroxyl group, a hydroxyl peak may not be present at 3200-3400 cm⁻¹ when measured using infrared spectroscopy. This indicates that the photoresist thin film according to the present invention exhibits hydrophobicity.

Hereinafter, embodiments and experimental examples of the present invention will be described in detail. However, the following embodiments are intended only to illustrate the present invention and are not intended to limit the invention to these embodiments.

### EMBODIMENT 1

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 2

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(CH₂CH₂I)Sn(NMe₂)) was injected for 20 seconds and purged. This process was performed 300 cycles.

### EMBODIMENT 3

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor ((nBu)₃Sn(NMe₂)) was injected for 20 seconds and purged. This process was performed 300 cycles.

### EMBODIMENT 4

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor ((nBu)₂(CH₂CH₂I)Sn(NMe₂)) was injected for 20 seconds and purged. This process was performed 300 cycles.

### EMBODIMENT 5

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor (tBuSn(NMe₂)) was injected for 20 seconds and purged. This process was performed 300 cycles.

### EMBODIMENT 6

A first precursor (iPrSn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 7

A first precursor (tBuSn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 8

A first precursor (C₃H₄Sn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 9

A first precursor (C₇H₇Sn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 10

A first precursor (tBuSn(OC(CH₃)₂Et)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 11

A first precursor (MeSn(NH₂)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 12

A first precursor (MeTe(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### EMBODIMENT 13

A first precursor (MeSn(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Te(NMe₂)) was injected for 20 seconds and purged. This process was performed 300 cycles.

### EMBODIMENT 14

A first precursor (MeTe(OCOEt)₃) and water were simultaneously injected into a chamber containing a silicon wafer substrate at a temperature of 50° C. to 100° C. (preferably 75° C.) for 15 seconds and purged. Then, a second precursor (Me₂(tBu)Te(NMe₂)) was injected for 20 seconds and purged. This process was performed 300 cycles.

### EMBODIMENT 15

A first precursor (Sn(NH₂)₄) and water were simultaneously injected into a chamber containing a silicon wafer substrate at a temperature of 50° C. to 100° C. (preferably 75° C.) for 15 seconds and purged. Then, a second precursor (Me₂(tBu)Sn(NMe₂)) was injected for 20 seconds and purged. This process was performed 300 cycles.

### COMPARATIVE EXAMPLE 1

In the process of introducing the second precursor, the process was performed including a reactant, rather than a process that does not include a reactant. Other conditions were the same as in embodiment 1.

### COMPARATIVE EXAMPLE 2

A first precursor (MeSn(OCOEt)₃) was used as a single precursor without a second precursor, and other conditions were the same as in embodiment 1.

### COMPARATIVE EXAMPLE 3

In the process of introducing the second precursor, the process was performed including a reactant, rather than a process that does not include a reactant. Other conditions were the same as in embodiment 13.

### EXPERIMENTAL EXAMPLE

Evaluation results of the experimental examples of the present invention are shown in Table 1 below.

TABLE 1

| | Thin film | | | |
|---|---|---|---|---|
| | thickness | Contact angle | Sensitivity | Hydroxy |
| | (nm) | with water | (mJ/cm²) | peak |
| Embodiment1 | 24.7 | 72.4 | 14.78 | ◯ |
| Embodiment2 | 25 | 89 | 14.69 | ◯ |
| Embodiment3 | 25 | 83 | 14.93 | ◯ |
| Embodiment4 | 24.8 | 88 | 14.84 | ◯ |
| Embodiment5 | 24.9 | 75.2 | 14.61 | ◯ |
| Embodiment6 | 23.9 | 77.6 | 14.69 | ◯ |
| Embodiment7 | 24.5 | 78.1 | 14.59 | ◯ |
| Embodiment8 | 24.9 | 76.9 | 14.65 | ◯ |
| Embodiment9 | 24.8 | 79.2 | 14.81 | ◯ |
| Embodiment10 | 25.1 | 78.5 | 14.76 | ◯ |
| Embodiment11 | 25 | 77.9 | 14.75 | ◯ |
| Embodiment12 | 25.3 | 79.3 | 14.37 | ◯ |
| Embodiment13 | 25.2 | 78.4 | 14.39 | ◯ |
| Embodiment14 | 24.8 | 78.1 | 14.31 | ◯ |
| Embodiment15 | 25 | 78.1 | 14.58 | ◯ |
| Comparative | 25.2 | 35 | Not evaluable | X |
| example 1 | | | | |
| Comparative | 25.1 | 37 | 15.04 | X |
| example 2 | | | | |
| Comparative | 25.3 | 42.3 | Not evaluable | X |
| example 3 | | | | |

### <Experimental Example 1> Thin Film Thickness Measurement

The thickness of the photoresist thin film generated by performing the processes of embodiments 1 to 15 and comparative examples 1 to 3 above was measured using an ellipsometer. The measured thickness was approximately 20 to 30 nm.

### <Experimental Example 2> Water Contact Angle

The contact angle of a metal oxide film is typically lower than 50°. However, the photoresist thin film according to the present invention has a contact angle of 60° or higher. The thin film of the present invention exhibits relatively hydrophobicity compared to a metal oxide film because the hydroxo group is removed and the side chain contains an alkyl chain.

### <Experimental Example 3> Coating Properties and Sensitivity

The photoresist thin film produced by performing the processes of embodiments 1 to 15 and comparative examples 1 to 3 were exposed to EUV radiation. After the exposure, a post-exposure bake (PEB) was performed at 170° C. for 120 seconds. The baked thin films were immersed in a developer and rinsed to form negative-tone images. The residual resist thickness was measured using an ellipsometer, and the sensitivity (Dose to gel) for each resist type is shown in Table 1. Referring to Table 1, embodiments 1 to 15 exhibited superior (i.e., lower) sensitivity compared to comparative example 2, which used a single precursor and CVD process.

Embodiment 15, which did not include a reactant during the modified layer formation step, exhibited superior sensitivity compared to comparative example 3, which included a reactant in the modified layer formation step.

In photoresists, a higher absorbance indicates a more superior sensitivity, and from this perspective, the order of superiority is In, Sn, Sb, and Te. Embodiments 12 to 14, which included Te among the metals, exhibited better sensitivity than embodiment 1, which included only Sn among the metals.

Comparative examples 1 and 3 were performed with reactants, resulting in metal oxide films devoid of photoreactive alkyl groups, making sensitivity evaluation impossible.

### <Experimental Example 4> Infrared Spectroscopy (IR) Analysis

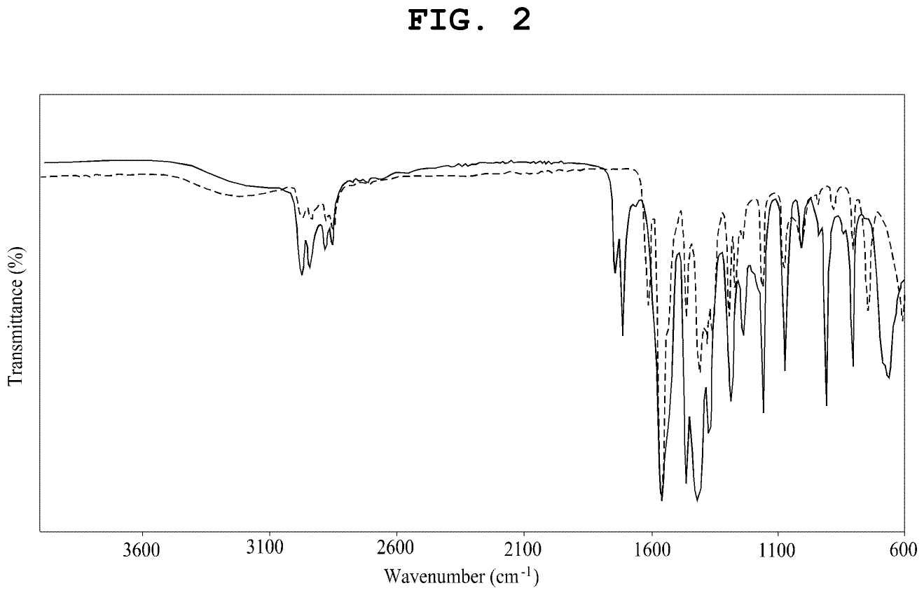

The results of infrared spectroscopy (IR) analysis of the photoresist thin films produced by performing the processes of embodiments 1 to 15 and comparative examples 1 to 3 at room temperature (typically 15 to 25° C.) using a Bruker Vertex 70 instrument are shown in Table 1 and FIG. 2.

Embodiments 1 to 15 did not exhibit a hydroxyl peak between 3200 cm⁻¹ and 3400 cm⁻¹, while comparative examples 1 to 3 exhibited a hydroxyl peak, as shown in Table 1.

FIG. 2 shows the IR analysis graphs of embodiment 1 and comparative example 2. The hydroxo peak is 3232.36 cm⁻¹, represented by a solid line for embodiment 1 and a dotted line for comparative example 2. Embodiment 1 uses a first precursor (MeSn(OCOEt)₃) and a second precursor (Me₂(tBu)Sn(NMe₂)), while comparative example 2 uses the first precursor (MeSn(OCOEt)₃) as a single precursor without the second precursor.

Referring to FIG. 2, the IR analysis results confirmed that the photoresist thin film according to the present invention does not exhibit a peak within the hydroxyl peak range (wavelength 3232.36 cm⁻¹). This indicates that the hydroxyl group has been removed.

The description of the present invention described above is for illustrative purposes, and those skilled in the art will understand that the present invention is easily modifiable into other specific forms without changing the technical idea or essential features of the present invention. Therefore, the embodiments described above should be understood in all respects as illustrative and not restrictive. For example, each component described as singular may be implemented in a distributed manner, and similarly, components described as distributed may also be implemented in a combined manner.

The scope of the present invention is represented by the claims described below, and all changes or modified forms derived from the meaning and scope of the claims and their equivalent concepts should be construed as being included in the scope of the present invention.

1. A method for forming a hydrophobic photoresist film, comprising:
injecting a first precursor and an oxygen source into a chamber in which a substrate is disposed, so as to form a film including hydrophilic groups on the substrate; and
injecting a second precursor to the chamber and thereby modifying the film including the hydrophilic groups, so as to form a modified layer.

2. The method for forming a hydrophobic photoresist film of claim 1, further comprising supplying a purge gas to the chamber after forming the film including hydrophilic groups, thereby removing an unreacted portion of the oxygen source.

3. The method for forming a hydrophobic photoresist film of claim 1, further comprising, after forming the modified layer, supplying a purge gas to the chamber to remove an unreacted portion of the second precursor.

4. The method for forming a hydrophobic photoresist film of claim 1, wherein the forming of the modified layer is performed without supplying a reactant.

5. The method for forming a hydrophobic photoresist film of claim 1, wherein the hydrophilic groups comprise one or more hydroxyl groups.

6. The method for forming a hydrophobic photoresist film of claim 1, wherein the first precursor comprises a compound represented by Chemical Formula 1 below: 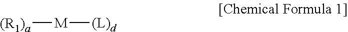
wherein a and d are integers that satisfy conditions 0≤a≤5, 0≤d≤5, and 0<a+d<5,
M is a Period 5 metal,
R₁ is selected from the group consisting of a linear, branched or cyclic alkyl group, a linear, branched or cyclic alkenyl group, and aryl group, and
L is each independently a hydrolyzable ligand.

7. The method for forming a hydrophobic photoresist film of claim 6, wherein the M is one metal selected from the group consisting of Te, Sb, Sn, and In.

8. The method for forming a hydrophobic photoresist film of claim 6, wherein the L is selected from the group consisting of an ester group, an amine group, an amide group, an alkoxy group, a carbonyl group, and an aldehyde group.

9. The method for forming a hydrophobic photoresist film of claim 6, wherein the R₁ comprises a branched alkyl group.

10. The method for forming a hydrophobic photoresist film of claim 6, wherein the second precursor comprises a compound represented by Chemical Formula 2 below: 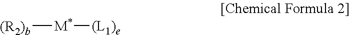
wherein b and e are integers that satisfy conditions 1≤b≤5, 0≤e≤5, and 1≤b+e≤5,
M* is a Period 5 metal,
R₂ is selected from the group consisting of a linear, branched or cyclic alkyl group, a linear, branched or cyclic alkenyl group, and aryl group, and
L₁ is a hydrolyzable ligand.

11. The method for forming a hydrophobic photoresist film of claim 10, wherein the M* is one metal selected from the group consisting of Te, Sb, Sn, and In.

12. The method for forming a hydrophobic photoresist film of claim 10, wherein the L₁ is selected from the group consisting of an ester group, an amine group, an amide group, an alkoxy group, a carbonyl group, and an aldehyde group.

13. The method for forming a hydrophobic photoresist film of claim 1, wherein the oxygen source is one selected from the group consisting of water, oxygen, ozone, and hydrogen peroxide.

14. The method for forming a hydrophobic photoresist film of claim 10, wherein at least one of the M or the M* is Te.

15. The method for forming a hydrophobic photoresist film of claim 14, wherein both of the M and the M* are Te.

16. A hydrophobic photoresist film, comprising a compound represented by chemical formula 3 below: 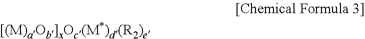
wherein M and M* are each independently a Period 5 metal,
R₂ is selected from the group consisting of a linear, branched or cyclic alkyl group, a linear, branched or cyclic alkenyl group, and an aryl group, and
a′≥4, b′≥8, c′≥4, d′≥8, e′≥8, x≥1.

17. The hydrophobic photoresist film of claim 16, wherein the hydrophobic photoresist film exhibits a contact angle with water of 60° or higher.

18. The hydrophobic photoresist film of claim 16, wherein infrared spectroscopy thereof presents no hydroxy peak at 3200-3400 cm⁻¹.

19. The hydrophobic photoresist film of claim 16, wherein the R₂ comprises a tert-butyl group or —CH₂CH₂I.

20. The hydrophobic photoresist film of claim 16, wherein at least one of the M or the M* comprises Te.
